(19) United States
(12) Patent Application Publication
(10) Pub. No.: US 2010/0178616 A1
(43) Pub. Date: Jul. 15, 2010

(54) METHOD OF MAKING A ROUGH SUBSTRATE

(75) Inventors: Chih-Sheng Lin, Tainan County (TW); Che-Hsiung Wu, Tainan County (TW)

Correspondence Address: MARSH, FISCHMANN & BREYFOGLE LLP, 8055 East Tufts Avenue, Suite 450, Denver, CO, 80237, US

(73) Assignee: UBILUX OPTOELECTRONICS CORPORATION, Tainan County (TW)

(21) Appl. No.: 12/651,846

(22) Filed: Jan. 4, 2010

(30) Foreign Application Priority Data
Jan. 9, 2009 (TW) 098100689

(51) Int. Cl. G03F 7/20

(52) U.S. Cl. 430/323; 430/324

(57) ABSTRACT

A method of making a rough substrate includes: (a) forming a first oxide layer; (b) coating a photoresist layer; (c) exposing and developing the photoresist layer; (d) etching parts of the first oxide layer such that parts of the first oxide layer are formed into a plurality of sacrificial protrusions; (e) removing the photoresist regions; (f) depositing on the substrate layer and the sacrificial protrusions a second oxide layer; (g) etching the second oxide layer so as to leave portions of the second oxide layer; and (h) etching additionally the sacrificial protrusions, the substrate layer, and the portions of the second oxide layer, thereby producing a plurality of flat recess bottom faces, and substrate protrusions.

### CROSS-REFERENCE TO RELATED APPLICATION

This application claims priority of Taiwanese application No. 098100689, filed on Jan. 9, 2009.

### BACKGROUND OF THE INVENTION

1. Field of the Invention

This invention relates to a method of making a substrate for a semiconductor device, more particularly to a method of making a substrate with a rough surface for growth of a semiconductor device thereon.

2. Description of the Related Art

A light-emitting device usually includes a substrate, an n-type semiconductor layer, a light-emitting layer, a p-type semiconductor layer, and electrodes. Light generated from recombination of electrons and holes is emitted in the light-emitting layer.

When light enters an interface between the p-type semiconductor layer and the electrodes at an angle larger than a critical angle, the light is reflected to propagate laterally in the semiconductor layers. However, the light loses its energy during the propagation, thereby lowering the external quantum efficiency. An existing method is generally carried out by processing a light-emitting diode chip to be of a hemispherical form or of a pyramidal form such that light enters the interface at an angle less than the critical angle so as to reduce light reflection. However, such processing is difficult and may damage the chip.

Another existing method includes roughening the surface of the light-emitting diode. However, the p-n junction may be damaged and the light-emitting efficiency may be adversely affected.

A conventional semiconductor device includes a substrate having recesses or protrusions for scattering light generated in the light-emitting layer, thereby increasing the external quantum efficiency. The recesses or protrusions in the substrate are created by mechanical polishing or etching. Since the recesses or protrusions are randomly generated, the crystallinity of the grown nitride semiconductor structure is lowered, which adversely affects the light-emitting efficiency. In addition, the method of making the substrate is complicated and incurs high labor and manufacturing costs.

U.S. Pat. No. 6,870,191 discloses a substrate provided with recesses/protrusions with a specific shape so as to increase crystallinity of the grown nitride semiconductor layers by virtue of the different growth rates of lateral and vertical growth of crystals. However, defects are easily produced at the interfaces of the nitride layers.

U.S. Patent Application Publication No. 2005/0179130 discloses a semiconductor device and a method of making the same. The semiconductor device includes a substrate formed with recesses/protrusions each of which includes at least two surfaces having different inclination angles. However, the method is complicated and incurs high manufacturing costs.

### SUMMARY OF THE INVENTION

Therefore, an object of the present invention is to provide a method of making a rough substrate for growth of a semiconductor device that can address the problems encountered in the aforesaid prior art.

According to the present invention, a method of making a rough substrate comprises: (a) forming a first oxide layer on a substrate layer; (b) coating a photoresist layer on the first oxide layer; (c) exposing and developing the photoresist layer to form a plurality of spaced-apart photoresist regions; (d) etching parts of the first oxide layer uncovered by the photoresist regions such that portions of the substrate layer are exposed and such that parts of the first oxide layer shielded by the photoresist regions are formed into a plurality of spaced-apart sacrificial protrusions on the substrate layer; (e) removing the photoresist regions on the sacrificial protrusions; (f) depositing on the substrate layer and the sacrificial protrusions a second oxide layer; (g) etching the second oxide layer so as to expose the sacrificial protrusions and portions of the substrate layer and so as to leave rounded lateral portions of the second oxide layer which surround the sacrificial protrusions, respectively, and which have a rounded surface profile; and (h) etching additionally the sacrificial protrusions and the substrate layer which have been exposed, and the rounded lateral portions of the second oxide layer which respectively surround the sacrificial protrusions until a plurality of flat recess bottom faces are formed in the substrate layer, thereby producing substrate protrusions protruding from the flat recess bottom faces.

### BRIEF DESCRIPTION OF THE DRAWINGS

Other features and advantages of the present invention will become apparent in the following detailed description of the preferred embodiments of this invention, with reference to the accompanying drawings, in which:

FIGS. 1a to 1h are sectional views to illustrate consecutive steps of the first preferred embodiment of a method of making a rough substrate according to this invention;

FIG. 2 is a sectional view of the rough substrate made by the first preferred embodiment;

FIGS. 3a to 3f are sectional views to illustrate consecutive steps of the second preferred embodiment of a method of making a rough substrate according to this invention;

FIG. 4 is a sectional view of the rough substrate made by the second preferred embodiment;

FIG. 5a is a top view of protrusions arranged in a matrix array; and

FIG. 5b is a top view of the protrusions arranged in a random pattern.

### DETAILED DESCRIPTION OF THE PREFERRED EMBODIMENTS

Before the present invention is described in greater detail with reference to the accompanying preferred embodiments, it should be noted herein that like elements are denoted by the same reference numerals throughout the disclosure.

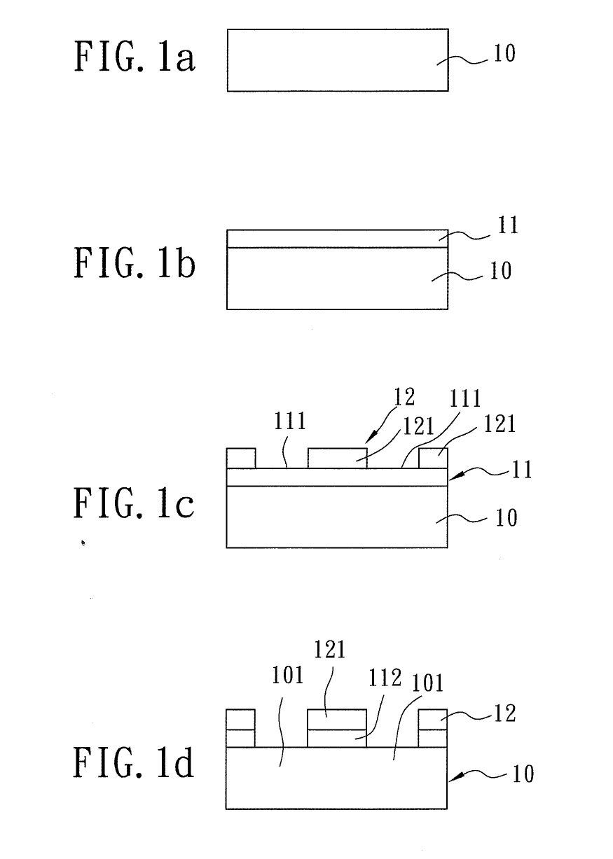

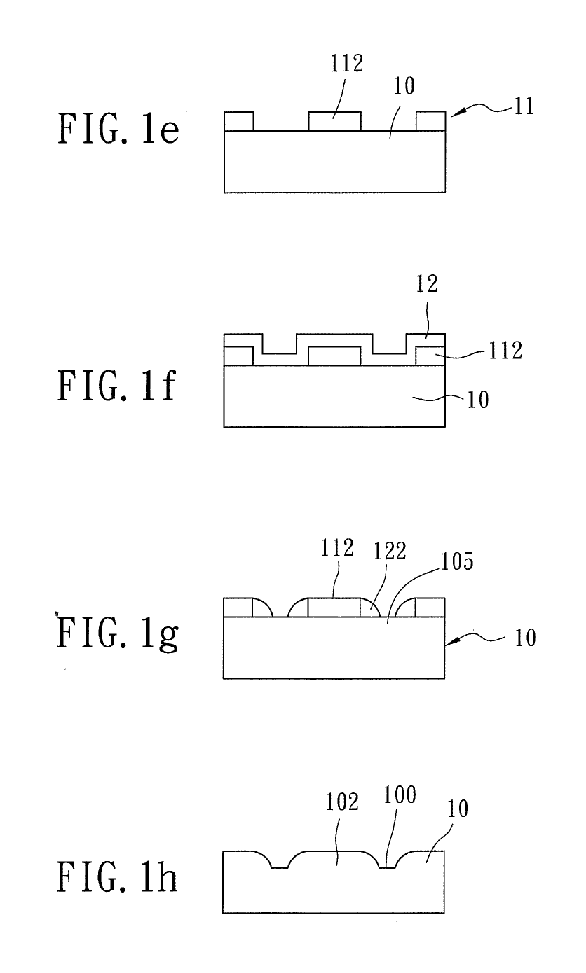

FIGS. 1a to 1h illustrate the consecutive steps of a method of making a rough substrate for growth of a semiconductor device according to the first preferred embodiment of this invention. The semiconductor device includes a plurality of semiconductor layers.

Referring to FIGS. 1a and 1b, a first oxide layer 11 is formed on a substrate layer 10.

Referring to FIG. 1c, a photoresist layer 12 is coated on the first oxide layer 11, and is exposed and developed to form a plurality of spaced-apart photoresist regions 121.

Referring to FIG. 1d in combination with FIG. 1c, parts 111 of the first oxide layer 11 uncovered by the photoresist regions 121 are etched such that portions 101 of the substrate layer 10 are exposed and such that parts of the first oxide layer 11 shielded by the photoresist regions 121 are formed into a plurality of spaced-apart sacrificial protrusions 112 protruding from the substrate layer 10.

Referring to FIG. 1e, the photoresist regions 121 on the sacrificial protrusions 112 are removed.

Referring to FIG. 1f, a second oxide layer 12 is deposited on the substrate layer 10 and the sacrificial protrusions 112.

Referring to FIG. 1g, the second oxide layer 12 is etched so as to expose the sacrificial protrusions 112 and portions 105 of the substrate layer 10 and so as to leave rounded lateral portions 122 of the second oxide layer 12 which surround the sacrificial protrusions 112, respectively, and which have a rounded surface profile. The rounded lateral portions 122 of the second oxide layer 12 are spaced apart from each other. The etching in this step may be wet etching or dry etching.

Referring to FIG. 1h in combination with FIGS. 1f and 1g, the sacrificial protrusions 112 and the portions 105 of the substrate layer 10 which have been exposed, and the rounded lateral portions 122 of the second oxide layer 12 which respectively surround the sacrificial protrusions 112 are additionally etched until a plurality of flat recess bottom faces 100 are formed in the substrate layer 10, thereby producing substrate protrusions 102 protruding from the flat recess bottom faces 100. The etching in this step may be dry etching.

The substrate layer 10 may be made from a suitable transparent or non-transparent material, or a conductive or nonconductive material. In this embodiment, the first and second oxide layers 11, 12 are made from silicon dioxide (SiO₂) or silicon nitride (SiN). The substrate layer 10 is made from a material selected from the group consisting of silicon (Si), sapphire, silicon carbide (SiC), spinel (MgAl₂O₄), aluminum nitride (AlN), copper tungsten (CuW), and combinations thereof.

It is worth mentioning that the sacrificial protrusions 112 and the rounded lateral portions 122 can serve as a mask for buffering the action of etching. Accordingly, when etching is conducted in step (1g) to etch the substrate layer 10, the portions 105 of the substrate layer 10 uncovered by the sacrificial protrusions 112 and the rounded lateral portions 122 are etched first and recessed. Portions of the substrate layer 10 below the sacrificial protrusions 112 and the rounded lateral portions 122 are etched next and formed into the substrate protrusions 102. The substrate protrusions 102 have a rounded surface profile corresponding in shape to the rounded lateral portions of the second oxide layer 12.

Preferably, the substrate protrusions 102 have the shape of a circle, an oval, a triangle, a quadrangle, a hexagon, a rhombus, or a polygon, when viewed from a top side of the substrate protrusions 102.

It is worth mentioning that each of the sacrificial protrusions 112 of the first oxide layer 11 and the rounded lateral portions 122 of the second oxide layer 12 can be varied in shape according to a desired light emitting power of the semiconductor device.

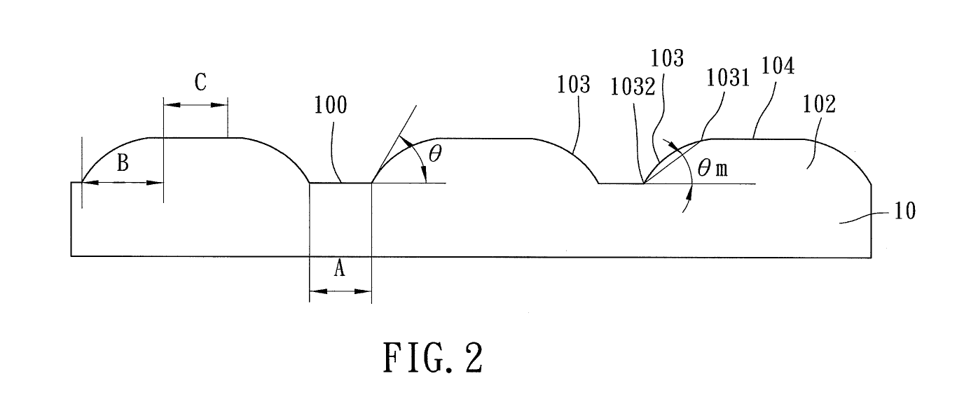

Referring to FIG. 2, the rough substrate made by the first preferred embodiment of the method includes a plurality of the substrate protrusions 102 protruding from the flat recess bottom faces 100. Each of the substrate protrusions 102 has a planar top surface 104, and a rounded sidewall 103 that extends annularly and downwardly from the planar top surface 102 to a contiguous one of the flat recess bottom faces 100. The substrate protrusions 102 are spaced apart from each other by a distance (A) ranging from 0.5 μm to 5 μm. The planar top surface 104 has a largest width (C) ranging from 0.5 μm to 5 μm. The rounded sidewall 103 has a top end 1031 meeting the planar top surface 104 and a bottom end 1032 meeting an adjacent one of the flat recess bottom faces 100. The rounded sidewall 103 has a length from the top end 1031 to the bottom end 1032 that produces a projected length (B) when projected onto a projection plane parallel to the flat recess bottom face 100. The projected length (B) is about 1-2 times a distance (A) between adjacent ones of the substrate protrusions 102. Moreover, the rounded sidewall 103 has a tangent line intersecting the bottom end 1032 of the rounded sidewall 103. The tangent line is inclined with a plane coplanar with the flat recess bottom faces 100 by an angle (θ) of about 25°-75°. The rounded sidewall 103 has a chordal line interconnecting the top and bottom ends 1031, 1032 thereof. The chordal line is inclined with a plane coplanar with the flat recess bottom faces 100 by an angle (θₘ) which is smaller than 45°.

By virtue of the substrate protrusions 102, defects of the semiconductor device can be reduced, thereby enhancing the external quantum efficiency and the light extraction efficiency.

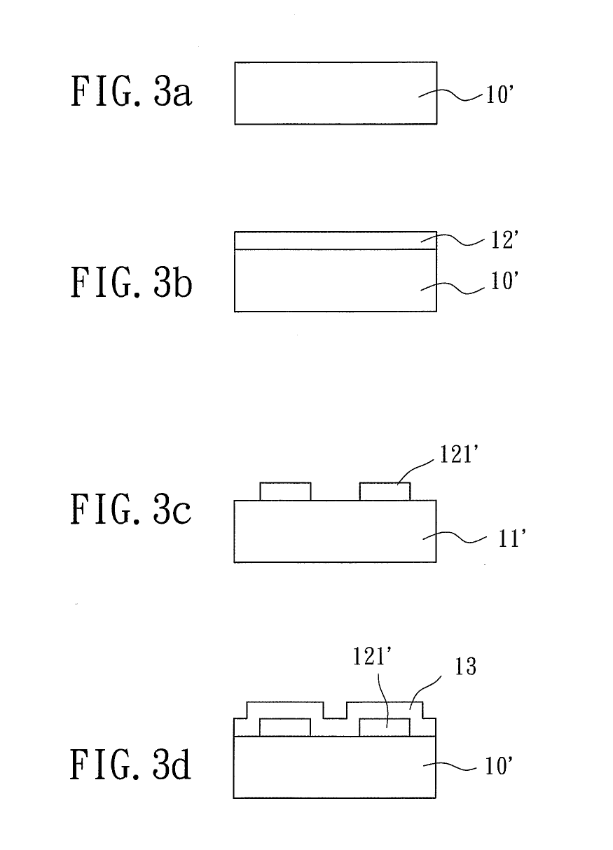

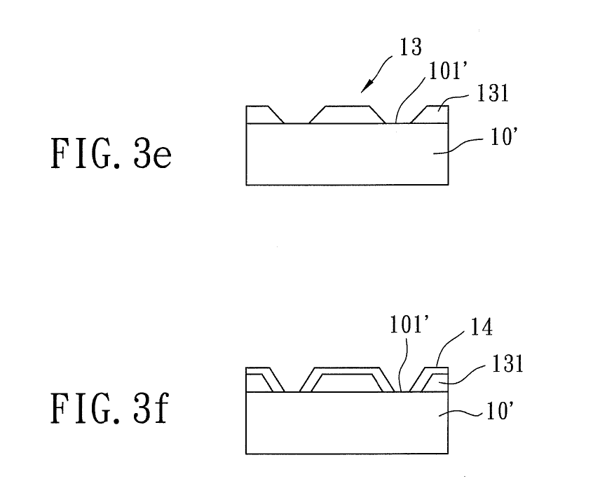

FIGS. 3a to 3f illustrate the consecutive steps of a method of making the rough substrate according to the second preferred embodiment of this invention.

Referring to FIGS. 3a and 3b, a photoresist layer 12′ is coated on a substrate layer 10′.

Referring to FIG. 3c, the photoresist layer 12′ is exposed and developed to form a plurality of spaced-apart photoresist regions 121′ on the substrate layer 10′.

Referring to FIG. 3d, a reflective layer 13 is deposited on portions of the substrate layer 10′ uncovered by the photoresist regions 121′ and on the photoresist regions 121′.

Referring to FIG. 3e in combination with FIG. 3d, the photoresist regions 121′ are lifted-off such that the reflective layer 13 on the photoresist regions 121′ is removed and the reflective layer 13 left on the substrate layer 10′ is formed into a plurality of space-apart protrusions 131 protruding from a surface 101′ of the substrate layer 10′.

Referring to FIG. 3f, the protrusions 131 are oxidized to produce oxidized skin layers 14 on the protrusions 131, respectively.

Preferably, the protrusions 131 have the shape of a circle, an oval, a triangle, a quadrangle, a hexagon, a rhombus, or a polygon, when viewed from above the protrusions 131.

Preferably, the reflective layer 13 is made of a material selected from the group consisting of aluminum (Al), silver (Ag), and combinations thereof. Alternatively, the reflective layer 13 can be a distributed Bragg reflector.

Preferably, the substrate layer 10′ is made from a material selected from the group consisting of silicon (Si), sapphire, carbon silicon (SiC), spinel (MgAl₂O₄), aluminum nitride (AlN), copper tungsten (CuW), and combinations thereof.

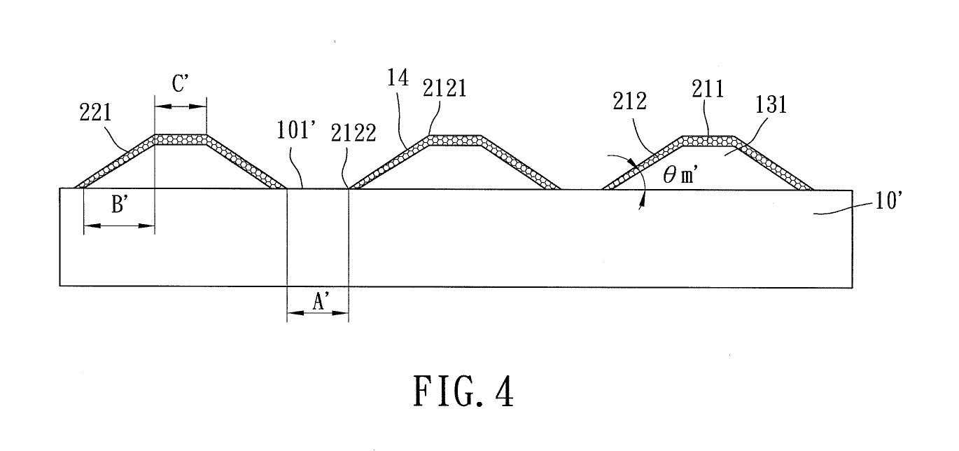

Referring to FIG. 4, the rough substrate made by the second preferred embodiment of the method includes a plurality of the protrusions 131. The protrusions 131 are spaced apart from each other by a distance (A′) ranging from 0.5 μm to 5 μm. Each of the protrusions 131 has a planar top surface 211, and a truncated cone-shaped sidewall 212 extending annularly and downwardly from the planar top surface 211. The planar top surface 211 has a width (C′) ranging from 0.5 μm to 5 μm. The truncated cone-shaped sidewall 212 has a top end 2121 meeting the planar top surface 211 and a bottom end 2122 meeting the surface 101′ of the substrate layer 10′. The truncated cone-shaped sidewall 212 has a length from the top end 2121 to the bottom end 2122 thereof, that produces a projected length (B′) on a projection plane coplanar with the surface 101′ of the substrate layer 10′. The projected length (B′) is 1-2 times a distance (A′) between adjacent ones of the protrusions 131.

In this embodiment, an inclining angle (θₘ′) of the truncated cone-shaped sidewall 212 with respect to the surface 101′ of the substrate layer 10′ is smaller than 45°.

Likewise, by virtue of the protrusions 131, defects of the semiconductor device can be reduced, thereby enhancing the external quantum efficiency and the light extraction efficiency.

In addition, by oxidizing the protrusions 131, the oxidized skin layers 14 on the protrusions 131 can be the same material as the substrate layer 10′.

For example, the substrate layer 10′ is sapphire (Al₂O₃) and the reflective layer 13 is made of aluminum (Al). When the reflective layer 13 is oxidized to produce the oxidized skin layer 14, the oxidized skin layer 14 is aluminum oxide (Al₂O₃) which is identical to the material of the sapphire substrate layer 10′. Therefore, the rough sapphire substrate has a surface layer that contains aluminum oxide (Al₂O₃) like the remaining part of the rough sapphire substrate.

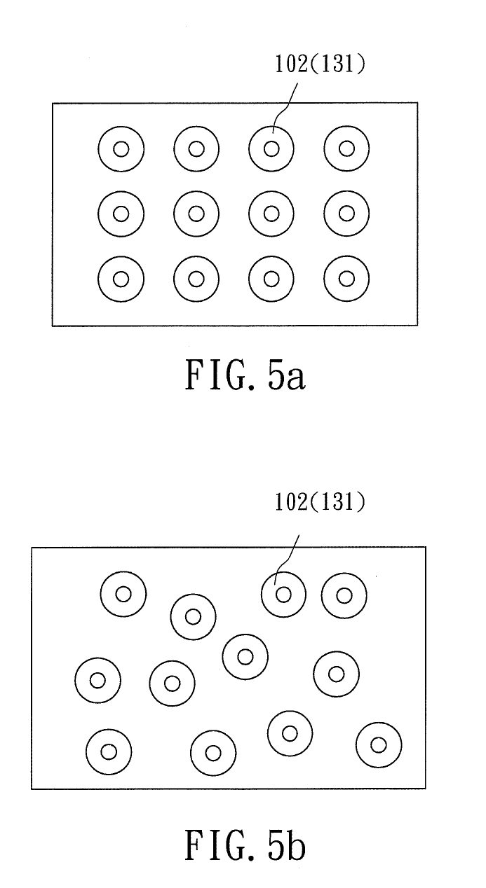

Referring to FIG. 5a, the substrate protrusions 102 made by the first preferred embodiment, or the protrusions 131 made by the second preferred embodiment have a circular profile when viewed from a top side and are arranged in a matrix array.

Referring to FIG. 5b, the substrate protrusions 102 or the protrusions 131 can be arranged in a random pattern.

It is worth mentioning that when the substrate protrusions 102 or protrusions 131 are regularly formed, external extraction efficiency of the light-emitting device can be increased and crystal defects in the semiconductor layers can be prevented when grown on the substrate of this invention.

With the invention thus explained, it is apparent that various modifications and variations can be made without departing from the spirit of the present invention. It is therefore intended that the invention be limited only as recited in the appended claims.

What is claimed is:

1. A method of making a rough substrate for growth of a semiconductor device that includes a plurality of semiconductor layers, the method comprising:
(a) forming a first oxide layer on a substrate layer;
(b) coating a photoresist layer on the first oxide layer;
(c) exposing and developing the photoresist layer to form a plurality of spaced-apart photoresist regions;
(d) etching parts of the first oxide layer uncovered by the photoresist regions such that portions of the substrate layer are exposed and such that parts of the first oxide layer shielded by the photoresist regions are formed into a plurality of spaced-apart sacrificial protrusions on the substrate layer;
(e) removing the photoresist regions on the sacrificial protrusions;
(f) depositing on the substrate layer and the sacrificial protrusions a second oxide layer;
(g) etching the second oxide layer so as to expose the sacrificial protrusions and portions of the substrate layer and so as to leave rounded lateral portions of the second oxide layer which surround the sacrificial protrusions, respectively, and which have a rounded surface profile; and
(h) etching additionally the sacrificial protrusions and the substrate layer which have been exposed, and the rounded lateral portions of the second oxide layer which respectively surround the sacrificial protrusions until a plurality of flat recess bottom faces are formed in the substrate layer, thereby producing substrate protrusions protruding from the flat recess bottom faces.

2. The method of claim 1, wherein the substrate protrusions have the shape of a circle, an oval, a triangle, a quadrangle, a hexagon, a rhombus, or a polygon, when viewed from a top side of the substrate protrusions.

3. The method of claim 1, wherein the substrate protrusions are spaced apart from each other by a distance ranging from 0.5 μm to 5 μm.

4. The method of claim 1, wherein each of the substrate protrusions has a planar top surface, and a rounded sidewall that extends annularly and downwardly from the planar top surface to a contiguous one of the flat recess bottom faces.

5. The method of claim 4, wherein the planar top surface has a largest width ranging from 0.5 μm to 5 μm.

6. The method of claim 4, wherein the rounded sidewall has a top end meeting the planar top surface and a bottom end meeting an adjacent one of the flat recess bottom faces, the rounded sidewall having a length from the top end to the bottom end that produces a projected length when projected onto a projection plane parallel to the flat recess bottom face, the projected length being 1-2 times a distance between adjacent ones of the substrate protrusions.

7. The method of claim 6, wherein the rounded sidewall has a tangent line intersecting the bottom end of the rounded sidewall, the tangent line being inclined with a plane coplanar with the flat recess bottom faces by an angle of about 25°-75°.

8. The method of claim 6, wherein the rounded sidewall has a chordal line interconnecting the top and bottom ends thereof, the chordal line being inclined with a plane coplanar with the flat recess bottom faces by an angle which is smaller than 45°.

9. The method of claim 1, wherein the substrate layer is made from a material selected from the group consisting of silicon, sapphire, silicon carbide, spinel, aluminum nitride, copper tungsten, and combinations thereof.

10. A method of making a rough substrate for growth of a semiconductor device thereon, the semiconductor device including a plurality of semiconductor layers, the method comprising:
(a) coating a photoresist layer on a substrate layer;
(b) exposing and developing the photoresist layer to form a plurality of spaced-apart photoresist regions on the substrate layer;
(c) depositing a reflective layer on portions of the substrate layer uncovered by the photoresist regions and on the photoresist regions;
(d) lifting-off the photoresist regions such that the reflective layer on the photoresist regions is removed and the reflective layer left on the substrate layer is formed into a plurality of space-apart protrusions protruding from a surface of the substrate layer; and
(e) oxidizing the protrusions to produce oxidized skin layers on the protrusions, respectively.

11. The method of claim 10, wherein the protrusions have the shape of a circle, an oval, a triangle, a quadrangle, a hexagon, a rhombus, or a polygon, when viewed from above the protrusions.

12. The method of claim 10, wherein the reflective layer is made of a material selected from the group consisting of aluminum, silver, and combinations thereof.

13. The method of claim 10, wherein the reflective layer is a distributed Bragg reflector.

14. The method of claim 10, wherein the protrusions are spaced apart from each other by a distance ranging from 0.5 μm to 5 μm.

15. The method of claim 10, wherein each of the protrusions has a planar top surface, and a truncated cone-shaped sidewall extending annularly and downwardly from the planar top surface.

16. The method of claim 15, wherein the planar top surface has a width ranging from 0.5 μm to 5 μm.

17. The method of claim 15, wherein the truncated cone-shaped sidewall has a top end meeting the planar top surface and a bottom end meeting the surface of the substrate layer, the truncated cone-shaped sidewall having a length from the top end to the bottom end thereof, a projected length of the length on a projection plane coplanar with the surface of the substrate layer being 1-2 times a distance between adjacent ones of the protrusions.

18. The method of claim 15, wherein an inclining angle of the truncated cone-shaped sidewall with respect to the surface of the substrate layer is smaller than

19. The method of claim 10, wherein the substrate layer is made a material selected from the group consisting of silicon, sapphire, silicon carbide, spinel, aluminum nitride, copper tungsten, and combinations thereof.
